(19) United States
(12) Patent Application Publication
(10) Pub. No.: US 2026/0245511 A1
(43) Pub. Date: Aug. 20, 2026

(54) DISPLAY DEVICE

(71) Applicant: SONY GROUP CORPORATION, Tokyo (JP)

(72) Inventor: Haruki TSUCHIYA, TOKYO (JP)

(21) Appl. No.: 18/872,240

(22) PCT Filed: Jun. 6, 2023
(86) PCT No.: PCT/JP2023/020920

§ 371 Date: Dec. 5, 2024

(30) Foreign Application Priority Data
Jun. 13, 2022 (JP) 2022-095299

(51) Int. Cl. G09G 3/3233; G09G 3/20

(52) U.S. Cl. CPC G09G 3/3233; G09G 3/2025; G09G 2300/0852; G09G 2300/0857; G09G 2310/08; G09G 2320/0233; G09G 2320/0252

(57) ABSTRACT

Accelerated display and improved image quality are achieved without relying on external correction. A display device that performs gradation display of a plurality of pixels in one frame including a plurality of subframes includes a light emitting element and a pixel circuit that controls a current for driving the light emitting element. The pixel circuit includes a current source that generates a current for driving the light emitting element, and a correction circuit that corrects a variation in the current generated by the current source. The plurality of subframes includes a subframe in which the light emitting element is driven after the variation is corrected by the correction circuit, and a subframe in which the light emitting element is driven without correcting the variation by the correction circuit.

### TECHNICAL FIELD

The present disclosure relates to a display device.

### BACKGROUND ART

Luminance of self-luminous elements such as light emitting diodes (LEDs) and organic light emitting diodes (OLEDs) varies for each element due to a manufacturing process, and unevenness occurs on a display screen. In order to suppress unevenness, there is known a technique of replacing a luminance value of a pixel absent region with an appropriate value and generating unevenness correction data on the basis of the replaced luminance value (see Patent Document 1).

Since self-luminous elements such as LEDs can be miniaturized, they are also used in small and high-resolution display devices called microdisplays. Microdisplays are widely used in display devices for virtual reality (VR) and augmented reality (Augmented Reality), head mounted displays, electronic viewfinders, and the like, and are expected to be increasingly used in the future.

### CITATION LIST

### Patent Document

Patent Document 1: Japanese Patent Application Laid-Open No. 2020-3694

### SUMMARY OF THE INVENTION

### Problems to be Solved by the Invention

The self-luminous elements such as LEDs may cause image quality degradation called roughness. A reduction in image quality of a self-luminous element such as an LED occurs due to variations in voltage-current (VI) characteristics and variations in current-luminance (IL) characteristics.

As a driving system of the self-luminous element, there are voltage driving and current driving. The voltage drive is likely to cause variations in VI characteristics. Current driving can reduce variations in VI characteristics, but a current source is required to perform current driving. In the current source, a variation in current output from the current source may occur due to a variation in the manufacturing process, which causes a decrease in image quality.

It is conceivable to provide a correction circuit for correcting the variation in the current output from the current source in the pixel. However, in order to correct the variation in the current output from the current source by providing the correction circuit in the pixel, a correction period required for correction processing is necessary, and it becomes difficult to accelerate the update period of pixel display.

Furthermore, it is also possible to provide a correction circuit for reducing the above-described variation outside the pixel instead of providing the correction circuit in the pixel.

However, if the above-described correction circuit is provided outside the pixel, the function of the correction circuit can be enhanced, but this causes an increase in cost.

Therefore, the present disclosure provides a display device capable of achieving accelerated display and improved image quality without relying on external correction.

### Solutions to Problems

In order to solve the above problem, according to the present disclosure, there is provided a display device that performs gradation display of a plurality of pixels in one frame including a plurality of subframes,
in which the pixels each include a light emitting element and a pixel circuit that controls a current for driving the light emitting element,
the pixel circuit includes
a current source that generates a current for driving the light emitting element, and
a correction circuit that corrects a variation in the current generated by the current source, and
the plurality of subframes includes a subframe in which the light emitting element is driven after the variation is corrected by the correction circuit and a subframe in which the light emitting element is driven without correcting the variation by the correction circuit.

Only one subframe in which the light emitting element is driven after the variation is corrected by the correction circuit may be provided in the plurality of subframes.

The subframe in which the light emitting element is driven after the variation is corrected by the correction circuit may be a head subframe among the plurality of subframes.

Two or more subframes in which the light emitting element is driven after the variation is corrected by the correction circuit may be provided in the plurality of subframes.

The subframe in which the light emitting element is driven after the variation is corrected by the correction circuit may include two or more subframes not adjacent to each other among the plurality of subframes.

The subframe in which the light emitting element is driven after the variation is corrected by the correction circuit may include two or more adjacent subframes among the plurality of subframes.

The subframe in which the light emitting element is driven after the variation is corrected by the correction circuit may include a predetermined number of adjacent subframes including a head subframe among the plurality of subframes.

Each of the plurality of pixels may be connected to any one of a plurality of gate lines, and
a plurality of the correction circuits included in the plurality of pixels may correct variations in current generated by the plurality of current sources in the plurality of pixels connected to the plurality of gate lines at the same timing.

The pixel circuit may include
a storage unit that stores pixel data; and
a first switching element that switches, for each of the plurality of subframes, whether or not to supply the light emitting element with a current corrected by the correction circuit on the basis of the pixel data stored in the storage unit.

The current source may include a second switching element cascode-connected to the first switching element, and
the correction circuit may correct a threshold voltage of the second switching element.

The first switching element may be turned on or off according to the pixel data stored in the storage unit, and
when the first switching element and the second switching element are turned on, the pixel circuit may cause a current corrected according to a threshold voltage of the second switching element to flow from the second switching element to the light emitting element through the first switching element.

A bias signal line that supplies a bias signal common to a plurality of the correction circuits included in the plurality of pixels may be included,
in which the second switching element may be turned on when the bias signal reaches a predetermined voltage level.

The correction circuit may include
a third switching element connected between a gate and a drain of the second switching element,
a first capacitor connected between the gate of the second switching element and the bias signal line, and
a second capacitor connected between the gate and the source of the second switching element.

The plurality of the correction circuits included in the plurality of pixels may synchronously turn on or off a plurality of the first switching elements, synchronously turn on or off a plurality of the second switching elements, and synchronously turn on or off a plurality of the third switching elements.

Conductivity types of the first switching element and the second switching element may be the same.

Conductivity types of the first switching element and the second switching element may be different from each other.

A fourth switching element that switches whether or not to set an anode of the light emitting element to a first reference voltage may be included,
in which the first switching element may be connected to the anode of the light emitting element, and
a cathode of the light emitting element may be set to a second reference voltage.

A fourth switching element that switches whether or not to set a cathode of the light emitting element to a first reference voltage may be included,
in which the first switching element may be connected to the cathode of the light emitting element, and
an anode of the light emitting element may be set to a second reference voltage.

The light emission periods of the light emitting elements in the plurality of subframes may be different from each other.

The light emission periods of the light emitting elements in the plurality of subframes may be the same.

### BRIEF DESCRIPTION OF DRAWINGS

FIG. 1 is a block diagram illustrating a schematic configuration of a display device according to the present disclosure.

FIG. 2 is a circuit diagram illustrating a circuit configuration of a pixel circuit in the display device according to the first embodiment.

FIG. 3 is an operation timing diagram of the pixel circuit of FIG. 2.

FIG. 4 is a detailed timing chart within a correction period of FIG. 3.

FIG. 5 is a circuit diagram of a pixel circuit according to a comparative example.

FIG. 6 is an operation timing diagram of the pixel circuit of FIG. 5.

FIG. 7 is a circuit diagram of a modification of the pixel circuit of FIG. 2.

FIG. 8 is an operation timing diagram according to a second modification of the pixel circuit of FIG. 2.

FIG. 9 is a circuit diagram of a pixel circuit in a display device according to a second embodiment.

FIG. 10 is a circuit diagram of a modification of the pixel circuit of FIG. 9.

FIG. 11 is an operation timing diagram of a pixel circuit according to a third embodiment.

FIG. 12 is an operation timing diagram according to a modification of FIG. 11.

FIG. 13A is a diagram illustrating an internal state of a vehicle from a rear side to a front side of the vehicle.

FIG. 13B is a diagram illustrating an internal state of the vehicle from an oblique rear side to an oblique front side of the vehicle.

FIG. 14A is a front view of a digital camera as a second application example of an electronic apparatus.

FIG. 14B is a rear view of the digital camera.

FIG. 15A is an external view of a head mounted display (HMD) as a third application example of the electronic apparatus.

FIG. 15B is an external view of smart glasses.

FIG. 16 is an external view of a television (TV) as a fourth application example of the electronic apparatus.

FIG. 17 is an external view of a smartphone as a fifth application example of the electronic apparatus.

### MODE FOR CARRYING OUT THE INVENTION

Hereinafter, embodiments of a display device will be described with reference to the drawings. Although main components of the display device will be mainly described below, the display device may have a component or function that is not illustrated or described. The following description does not exclude components and functions that are not illustrated or described.

### Schematic Configuration of Display Device

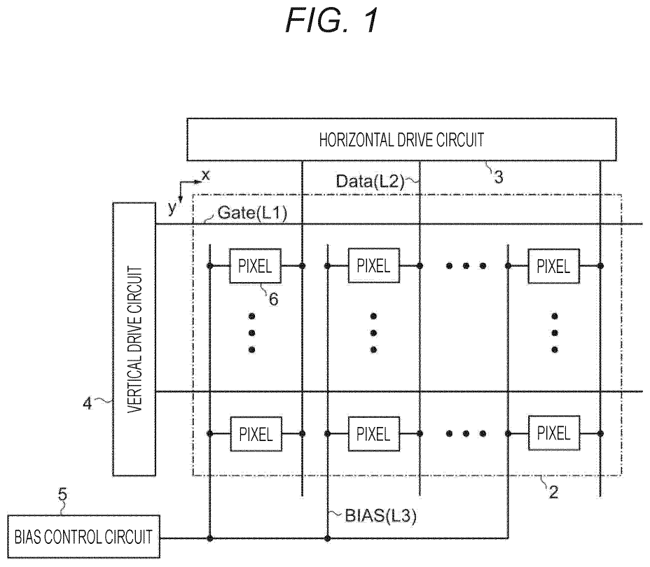

FIG. 1 is a block diagram illustrating a schematic configuration of a display device 1 according to the present disclosure. The display device 1 of FIG. 1 includes a pixel array unit 2, a horizontal drive circuit 3, a vertical drive circuit 4, and a bias control circuit 5.

The pixel array unit 2 includes a plurality of pixels 6 arranged in a first direction (horizontal direction) X and a second direction (vertical direction) Y. The internal configuration of the pixel 6 will be described later.

The horizontal drive circuit 3 outputs pixel data Data via a plurality of data lines L2 arranged at regular intervals in the horizontal direction X and extending in the vertical direction Y. The pixel data Data output via each data line L2 is supplied to the plurality of pixels 6 connected to respective data lines L2.

The vertical drive circuit 4 outputs a gate signal Gate via a plurality of gate lines L1 arranged at regular intervals in the vertical direction Y and extending in the horizontal direction X. The gate signal Gate output via each gate line L1 is supplied to the plurality of pixels 6 connected to respective gate lines L1.

The bias control circuit 5 supplies a common bias signal BIAS to all the pixels 6 in the pixel array unit 2 via a bias signal line L3. The bias signal BIAS is a binary signal that can take a high potential or a low potential.

Each pixel 6 in the pixel array unit 2 includes a light emitting element and a pixel circuit (not illustrated in FIG. 1). The light emitting element is a self-luminous element such as an LED or an OLED. The display device 1 according to the present disclosure performs gradation display by a pulse width modulation (PWM) modulation method. In a pulse width modulation method, one frame is divided into a plurality of subframes, and the light emitting element is caused to emit light in each subframe. A light emission period of the light emitting element is determined for each subframe, and the light emitting element is caused to emit light in the light emission period corresponding to the pixel data Data by selecting a subframe for each pixel 6, thereby implementing gradation display.

Furthermore, the pixel circuit according to the present disclosure performs current drive for causing a light emitting element to emit light by applying a current to the light emitting element. Accordingly, although a current source is provided in the pixel circuit, the current output from the current source may vary, and thus a correction circuit for correcting the variation in current is provided for each pixel circuit. The pixel circuit according to the present disclosure employs a current source collective correction method for collectively correcting current sources in the pixel circuits of all the pixels 6. The circuit configuration and the operation timing of the pixel circuit according to the present disclosure can take a plurality of forms. Hereinafter, representative circuit configurations and operation timings of the pixel circuits will be sequentially described.

### First Embodiment

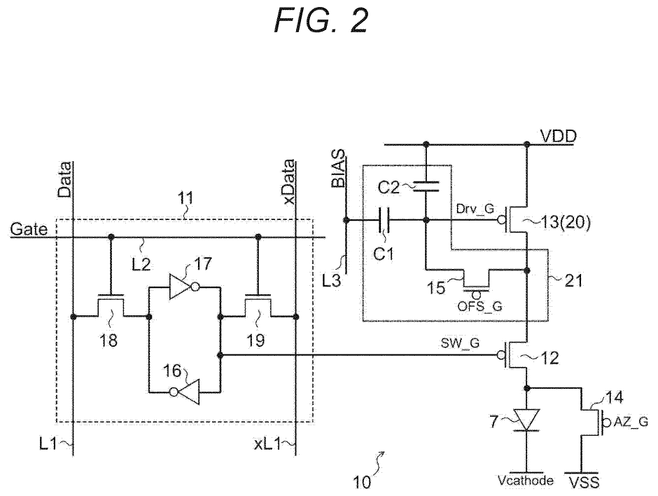

FIG. 2 is a circuit diagram illustrating a circuit configuration of the pixel circuit 10 in the display device 1 according to the first embodiment. The pixel circuit 10 of FIG. 2 includes a memory 11, a switch transistor (first switching element) 12, a drive transistor (second switching element) 13, a reset transistor (fourth switching element) 14, an offset transistor (third switching element) 15, a first capacitor C1, and a second capacitor C2.

The memory 11 is connected to a pair of data lines L1 and xL1 (hereinafter, a first data line L1 and a second data line XL1) output from the horizontal drive circuit 3. The first data line L1 and the second data line xL1 complementarily output the pixel data Data. Complementary output means that signals whose logic is opposite to each other are output. Note that, in FIG. 1, the second data line xL1 is not illustrated.

The memory 11 is, for example, a static random access memory (SRAM), and includes two inverters (hereinafter, a first inverter 16 and a second inverter 17) connected in a ring shape and two transistors (a first transistor 18 and a second transistor 19).

By connecting the first inverter 16 and the second inverter 17 in a ring shape, it is possible to stably hold the pixel data Data and xData. Each of the first inverter 16 and the second inverter 17 can include two transistors. The first transistor 18 is connected between an output node of the first inverter 16 and the first data line L1. The second transistor 19 is connected between an output node of the second inverter 17 and the second data line xL1.

The first transistor 18 and the second transistor 19 are, for example, N-channel Metal-Oxide-Semiconductor (NMOS) transistors. A gate of the first transistor 18 and a gate of the second transistor 19 are connected to the common gate line L2.

When the gate signal Gate on the gate line L2 becomes a high potential, the first transistor 18 and the second transistor 19 are turned on, and the pixel data Data and xData of the first data line L1 and the second data line xL1 are held by the first inverter 16 and the second inverter 17.

A cathode of the light emitting element 7 is connected to a reference voltage Vcathode node having a fixed voltage level. A reset transistor 14 is connected between an anode of the light emitting element 7 and a ground potential VSS node. The reset transistor 14 is, for example, a P channel Metal-Oxide-Semiconductor (PMOS) transistor. A reset signal AZ_G is input to a gate of the reset transistor 14. When the reset signal AZ_G becomes a low potential, the reset transistor 14 is turned on, and an anode potential of the light emitting element 7 becomes the ground potential VSS. During a period in which the reset transistor 14 is on, the current flowing through the switch transistor 12 flows through the reset transistor 14, so that the current does not flow through the light emitting element 7 and the light emitting element 7 does not emit light.

When the reset signal AZ_G is at a high potential, the reset transistor 14 is turned off. In this state, a current can flow between the anode and the cathode of the light emitting element 7.

A drive transistor 13 and a switch transistor 12 are cascode-connected between a power supply potential VDD node and the anode of the light emitting element 7. More specifically, a source of the drive transistor 13 is connected to the power supply potential VDD node, a drain of the drive transistor 13 is connected to a source of the switch transistor 12, and a drain of the switch transistor 12 is connected to the anode of the light emitting element 7. A gate of the switch transistor 12 is connected to the output node of the second inverter 17 in the memory 11.

The first capacitor C1 is connected between a gate of the drive transistor 13 and the bias signal line L3. The second capacitor C2 is connected between the gate of the drive transistor 13 and the power supply potential VDD node.

The drive transistor 13 in the pixel circuit 10 of FIG. 2 constitutes a current source 20. Furthermore, the offset transistor 15, the first capacitor C1, and the second capacitor C2 in the pixel circuit 10 constitute a correction circuit 21 for correcting variations in a threshold voltage of the drive transistor 13. That is, the correction circuit 21 corrects a variation in the current source 20 including the drive transistor 13.

The correction circuit 21 holds a charge corresponding to the threshold voltage of the drive transistor 13 in the first capacitor C1 and the second capacitor C2. Thus, when the bias signal line L3 is set to a low potential, a current according to the threshold voltage of the drive transistor 13 can flow between the source and the drain of the drive transistor 13.

That is, when the drive transistor 13 is in an on state, the correction circuit 21 causes a current taking the threshold voltage of the drive transistor 13 into consideration to flow between the source and the drain of the drive transistor 13.

A plurality of correction circuits 21 in the plurality of pixel circuits 10 corresponding to the plurality of pixels 6 performs correction processing on all the pixels 6 at the same timing. More specifically, the plurality of correction circuits 21 corresponding to the plurality of pixels 6 synchronously turns on or off the plurality of switch transistors 12, synchronously turns on or off the plurality of drive transistors 13, and synchronously turns on or off the plurality of offset transistors 15.

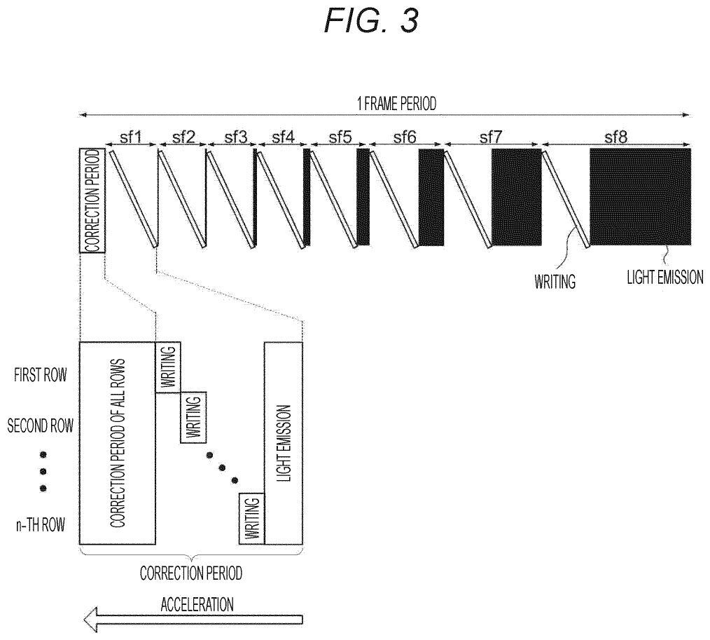

FIG. 3 is an operation timing diagram of the pixel circuit 10 of FIG. 2. As described above, the display device 1 according to the present disclosure performs the gradation display of the pulse width modulation method. Specifically, one frame period is divided into a plurality of subframe periods, and the light emission period of the light emitting element 7 is made different for each subframe period. In the example of FIG. 3, one frame is divided into eight subframes sf1 to sf8, and among the subframes sf1 to sf8, a subframe with a larger number has a longer light emission period. The longer the light emission period, the higher the light emission luminance.

The pixel data Data is, for example, 8 bits, and each bit of pixel data Data is associated with any subframe. More specifically, the least significant bit of the pixel data Data is associated with the subframe sf1, and the most significant bit of the pixel data Data is associated with the subframe sf8.

By performing writing to the memory 11 in the pixel circuit 10 and light emission of the light emitting element 7 for each bit of the pixel data Data in one frame, it is possible to perform gradation display for each pixel 6. More specifically, the light emitting element 7 emits light when the corresponding bit of the pixel data Data is 1, and the light emitting element 7 does not emit light when the corresponding bit is zero. The higher the bit of the pixel data Data, the longer the light emission period of the light emitting element 7.

FIG. 3 illustrates an example in which one frame is divided into eight subframes, but the number of subframes is arbitrary, and actually, the number of subframes corresponding to the bit length of the pixel data Data is provided. As the bit length of the pixel data Data increases, the number of subframes also increases, the number of gradations increases, and the image quality is improved.

In the display device 1 according to the first embodiment, a correction period for performing correction processing by the correction circuit 21 is provided immediately before the head subframe sf1 in one frame. The correction circuit 21 holds charges according to the threshold voltage of the drive transistor 13 in the first capacitor C1 and the second capacitor C2 by switching control of on/off of the switch transistor 12 and the offset transistor 15 and potential control of the bias signal line L3. The charges held in the first capacitor C1 and the second capacitor C2 are held over a subsequent subframe.

Thus, during each light emission period of the first to eighth subframes, a current corresponding to the threshold voltage of the drive transistor 13 can be supplied to the anode of the light emitting element 7. Therefore, even if the threshold voltage of the drive transistor 13 varies, a variation in the light emission luminance of the light emitting element 7 can be suppressed.

More specifically, when the correction processing by the correction circuit 21 is completed, light emission processing for each of the subframes sf1 to sf8 is performed. For example, in the subframe sf1, write processing of storing the pixel data Data in the memory 11 in each pixel 6 is performed for each pixel row arranged at regular intervals in the vertical direction Y and each extending in the horizontal direction X.

Thereafter, the light emitting elements 7 in all the pixels 6 are caused to emit light at the same timing.

As described above, in the first embodiment, before starting the processing of the head subframe sf1 among the eight subframes sf1 to sf8 obtained by dividing one frame into eight, the correction period by the correction circuit 21 is provided to correct a variation in the current source 20 including the drive transistor 13. This correction result is effective in the subsequent light emission processing of the eight subframes sf1 to sf8, and it is not necessary to perform the correction processing by the correction circuit 21 between light emission processes of the subframes sf1 to sf8. Thus, the ratio of the correction period to one frame period can be suppressed to be low, and accordingly, the display speed can be increased and the light emission period can be expanded.

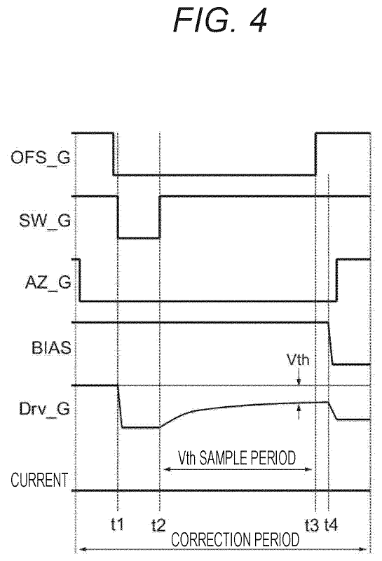

FIG. 4 is a detailed timing diagram within the correction period of FIG. 3. Before time t1, the bias signal BIAS has a high potential, the drive transistor 13 is off, the offset transistor 15 is off, and the reset transistor 14 is on. Thus, the anode of the light emitting element 7 becomes the ground potential VSS. Data 1 is stored in the memory 11 for correction processing.

At time t1, a gate signal OFS_G of the offset transistor 15 goes to a low level, and the offset transistor 15 is turned on.

Furthermore, although not illustrated in FIG. 4, the gate signal Gate is set to the low level. Thus, a gate signal SW_G of the switch transistor 12 connected to an output node of the memory 11 becomes a low potential, and the switch transistor 12 is turned on. Therefore, a drain voltage of the drive transistor 13 decreases. Since the offset transistor 15 is on, a gate voltage Drv_G of the drive transistor 13 also decreases.

Data 0 is written to the memory 11 at time t2. Thus, the gate signal SW_G of the switch transistor 12 connected to the output node of the memory 11 goes to a high level. Thus, the switch transistor 12 is turned off. At this time, since the offset transistor 15 is still on, the gate voltage of the drive transistor 13 gradually increases. When the voltage between the gate and the source of the drive transistor 13 matches the threshold voltage of the drive transistor 13 (around time t3), the gate voltage of the drive transistor 13 is stabilized. When the gate voltage of the drive transistor 13 is stabilized, charges corresponding to the threshold voltage of the drive transistor 13 are held in the first capacitor C1 and the second capacitor C2.

When the offset transistor 15 is turned off at time t3 and then the potential of the bias signal line L3 decreases at time t4, the gate voltage Drv_G of the drive transistor 13 decreases. The gate voltage Drv_G of the drive transistor 13 at this time point becomes a voltage level corresponding to the threshold voltage of the drive transistor 13.

Thereafter, the subframe sf1 is started, and if the corresponding bit of the pixel data Data is 1, 1 is written into the memory 11. When the writing of the pixel data Data to the memory 11 is completed for all the pixel rows, a current corresponding to the threshold voltage of the drive transistor 13 flows from the drive transistor 13 to the light emitting element 7 through the switch transistor 12, and the light emitting element 7 emits light with luminance corresponding to the current.

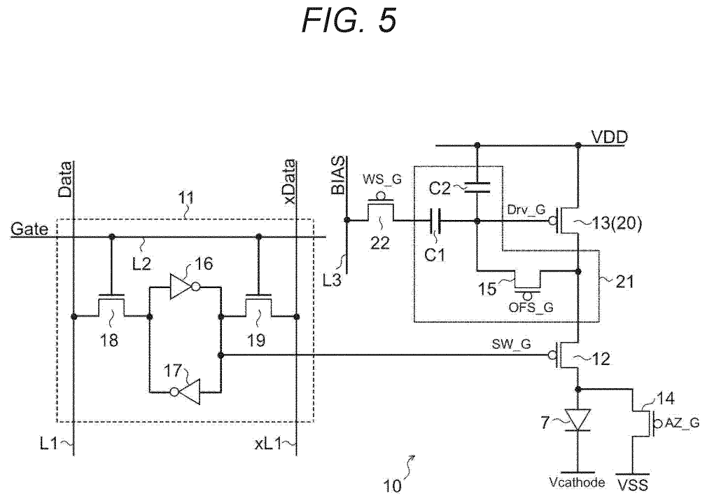

FIG. 5 is a circuit diagram of a pixel circuit 10 according to a comparative example. In the pixel circuit 10 of FIG. 5, the same components as those of the pixel circuit 10 of FIG. 2 are denoted by the same reference numerals, and differences will be mainly described below.

The pixel circuit 10 in FIG. 5 is common to the pixel circuit 10 in FIG. 4 in including a correction circuit 21 for correcting a variation in threshold voltage of the drive transistor 13. However, the correction circuit 21 in the pixel circuit 10 of FIG. 5 includes a writing transistor 22 in addition to the circuit configuration of the correction circuit 21 of FIG. 4. The writing transistor 22 is connected between the bias signal line L3 and one end of the first capacitor C1. The writing transistor 22 is turned on or off by the logic of the control signal WS_G. The control signal WS_G is turned on each time the pixel data Data of each pixel row is written to the memory 11. Thus, the correction circuit 21 corrects the variation in the threshold voltage of the drive transistor 13 for each pixel row.

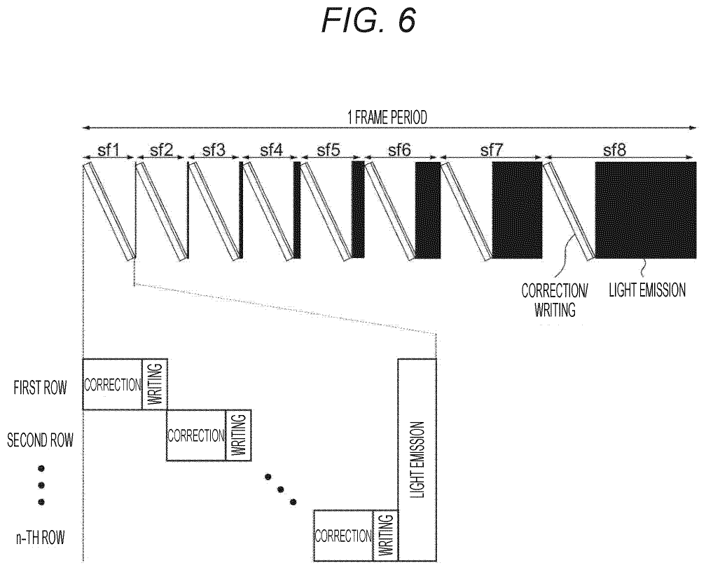

FIG. 6 is an operation timing diagram of the pixel circuit 10 of FIG. 5. The pixel circuit 10 in FIG. 5 performs gradation display by the pulse width modulation method, similarly to the pixel circuit 10 in FIG. 2. More specifically, the pixel circuit 10 in FIG. 5 divides one frame into a plurality of subframes, and makes the light emission period of the light emitting element 7 different for each subframe. The pixel circuit 10 in FIG. 5 performs correction processing by the correction circuit 21 for each pixel row in each subframe. Accordingly, as illustrated in FIG. 6, it is necessary to provide a correction period for each subframe, and the light emission period of the light emitting element 7 in each subframe period cannot be lengthened. Thus, in the pixel circuit 10 of FIG. 5, it is difficult to shorten the subframe period and increase the number of subframes, and it is not possible to achieve acceleration and improvement in luminance.

In the example of FIG. 3, the correction period by the correction circuit 21 is provided before the processing of the head subframe sf1 is started, but the correction period may be provided before the processing of subframes other than the head subframe sf1 is started. However, when the correction period is provided before the second and subsequent subframes, a subframe in which the light emission processing is performed on the basis of threshold correction in the immediately preceding frame period is partially included.

The pixel circuit 10 according to the first embodiment is characterized by including, among a plurality of subframes obtained by dividing one frame, a subframe in which the light emitting element 7 is driven after the variation is corrected by the correction circuit 21, and a subframe in which the light emitting element 7 is driven without correcting the variation by the correction circuit 21. As described in an embodiment to be described later, a correction period may be provided before processing of two or more subframes is started.

In the pixel circuit 10 of FIG. 2, all the transistors in the pixel circuit 10 are PMOS transistors, but the conductivity type of the transistors is arbitrary, and at least some of the transistors in the pixel circuit 10 may be NMOS transistors.

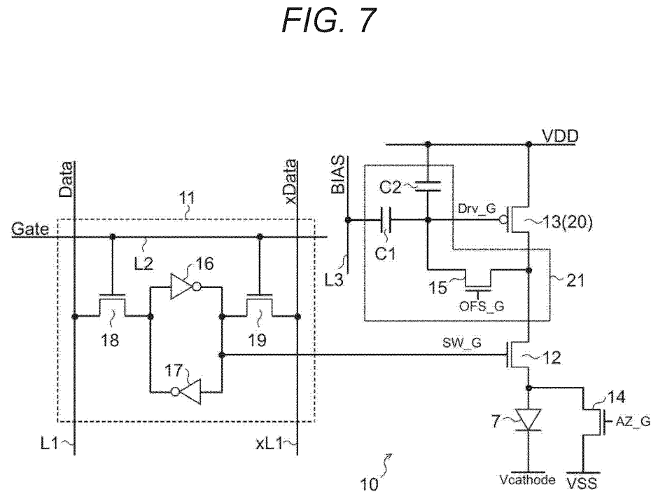

FIG. 7 is a circuit diagram of a modification of the pixel circuit 10 of FIG. 2. The pixel circuit 10 of FIG. 7 is different from the pixel circuit 10 of FIG. 2 in conductivity types of the switch transistor 12, the offset transistor 15, and the reset transistor 14. More specifically, the switch transistor 12, the offset transistor 15, and the reset transistor 14 in the pixel circuit 10 in FIG. 7 are all NMOS transistors. The drain of the switch transistor 12 is connected to the drain of the drive transistor 13.

In the pixel circuit 10 of FIG. 7, it is necessary to reverse the logics of the pixel data Data stored in the memory 11 to that of the pixel circuit 10 of FIG. 2. An output signal of the memory 11 is the gate signal SW_G of the switch transistor 12, and the switch transistor 12 is turned on when the gate signal SW_G is at a high potential.

Furthermore, in the pixel circuit 10 of FIG. 7, the logics of the offset signal OFS_G input to the gate of the offset transistor 15 and the reset signal AZ_G input to the gate of the reset transistor 14 need to be reversed from that of the pixel circuit 10 of FIG. 2.

As in FIG. 3, the pixel circuit 10 in FIG. 7 performs correction processing by the correction circuit 21 before the head subframe sf1.

In the pixel circuit 10 of FIG. 2, as illustrated in the operation timing diagram of FIG. 3, the light emission periods of the respective subframes within one frame period are different from each other, but the light emission periods of the respective subframes may be the same.

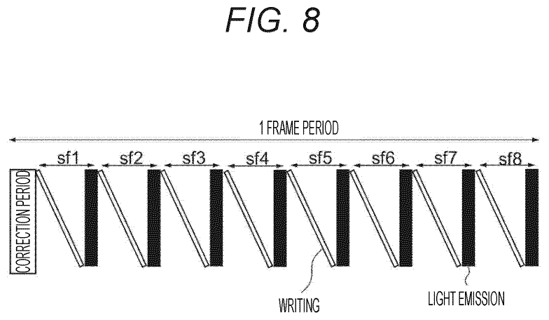

FIG. 8 is an operation timing diagram according to a second modification of the pixel circuit 10 of FIG. 2. FIG. 8 illustrates an example in which light emission periods in eight subframes sf1 to sf8 included in one frame are the same. In the case of FIG. 8, it is necessary to devise, for example, that the high-order bits of the pixel data causes two or more subframes to emit light instead of allocating any subframe to each bit of the pixel data.

As described above, the length of the light emission period in each subframe is arbitrary. By causing the light emitting element 7 to emit light in one or a plurality of subframes according to the pixel data Data, it is possible to perform gradation display according to the pixel data Data.

In the example of FIG. 8, since the light emission period of each subframe is the same, the number of gradations is smaller than that in FIG. 3, but there is no subframe having a long light emission period, and thus display can be accelerated. As described above, in the first embodiment, in a case where gradation display is performed by the pulse width modulation method, variation in threshold voltage of the drive transistor 13 in the pixel circuit 10 is corrected before the start of the head subframe among the plurality of subframes included in one frame. In each subframe, since the current flows to the light emitting element 7 by reflecting the result of the correction processing of the correction circuit 21, it is not necessary to provide the correction period in each subframe.

Thus, it is possible to perform the light emission processing of the plurality of subframes after correcting the variation in the current of the current source 20 only by providing one correction period in one frame. Therefore, since the number of correction periods can be reduced, one frame period can be shortened, the number of subframes can be increased, or the light emission period in each subframe can be lengthened, so that it is possible to increase the speed, improve the display quality, and improve the luminance.

### Second Embodiment

In the first embodiment, the cathode voltage of the light emitting element 7 in the pixel circuit 10 is fixed, and the current flowing through the anode is controlled to perform gradation display. On the other hand, in a second embodiment described below, the anode voltage of the light emitting element 7 is fixed, and the current flowing through the cathode is controlled to perform gradation display.

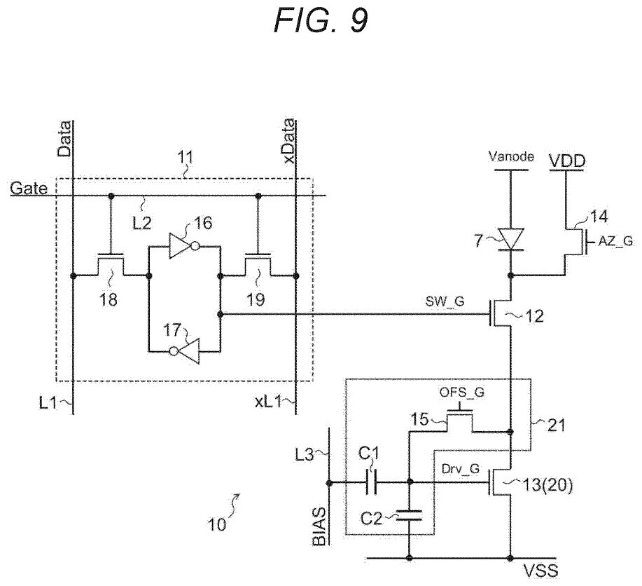

FIG. 9 is a circuit diagram of a pixel circuit 10 in a display device 1 according to the second embodiment. The pixel circuit 10 in FIG. 9 supplies a fixed reference voltage Vanode to the anode of the light emitting element 7 and controls the current flowing through the cathode of the light emitting element 7. The switch transistor 12, the drive transistor 13, the offset transistor 15, and the reset transistor 14 in the pixel circuit 10 in FIG. 9 are NMOS transistors.

In the pixel circuit 10 of FIG. 9, the switch transistor 12 and the drive transistor 13 are cascode-connected between the cathode of the light emitting element 7 and the ground potential VSS node. The offset transistor 15 is connected between the drain of the switch transistor 12 and the gate of the drive transistor 13. The first capacitor C1 is connected between the gate of the drive transistor 13 and the bias signal line L3. The second capacitor C2 is connected between the source of the offset transistor 15 (the gate of the drive transistor 13) and the ground potential VSS node. The reset transistor 14 is connected between the power supply potential VDD node and the cathode of the light emitting element 7.

When the output node of the memory 11 (the gate signal SW_G of the switch transistor 12) becomes a high potential, the switch transistor 12 is turned on, and the source voltage rises. At this point, the reset transistor 14 is turned on, and the source voltage of the switch transistor 12 and the drain voltage of the drive transistor 13 are at the power supply potential VDD. Furthermore, at this time point, the offset transistor 15 is on, and the drive transistor 13 is turned on.

Thereafter, when the output node of the memory 11 becomes a low potential and the switch transistor 12 is turned off, the drain voltage of the drive transistor 13 gradually decreases. In a case where the offset transistor 15 is on and the bias signal line L3 has a low potential, charges corresponding to the threshold voltage of the drive transistor 13 are held in the first capacitor C1 and the second capacitor C2.

Thereafter, when the reset transistor 14 is turned off, when the output node of the memory 11 becomes a high potential, a current corresponding to the threshold voltage of the drive transistor 13 flows from the cathode of the light emitting element 7 to the ground voltage VSS node through the switch transistor 12 and the drive transistor 13, and the light emitting element 7 emits light.

The switch transistor 12, the offset transistor 15, and the reset transistor 14 in FIG. 9 can also be configured by PMOS transistors.

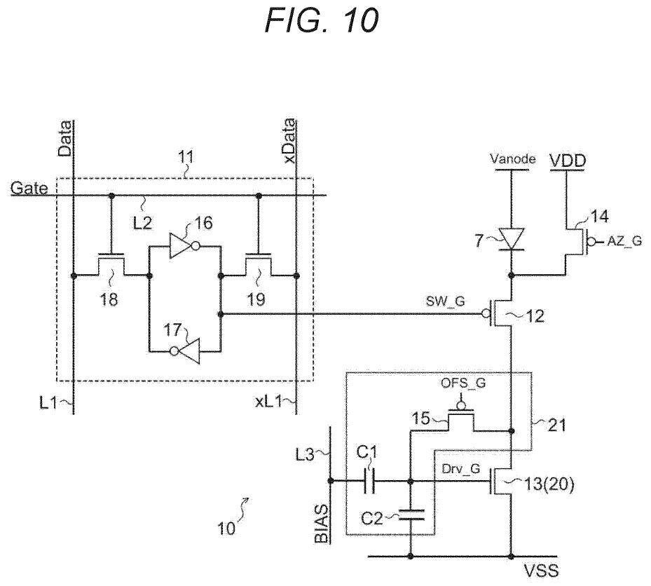

FIG. 10 is a circuit diagram of a modification of the pixel circuit 10 of FIG. 9. The switch transistor 12, the offset transistor 15, and the reset transistor 14 in FIG. 10 are constituted by PMOS transistors.

In the pixel circuit 10 of FIG. 10, the logic of the pixel data Data stored in the memory 11 needs to be reversed from that of the memory 11 in the pixel circuit 10 of FIG. 9. Furthermore, in the pixel circuit 10 of FIG. 10, the logics of the offset signal input to the gate of the offset transistor 15 and the reset signal input to the gate of the reset transistor 14 need to be reversed from those of the offset transistor 15 and the reset transistor 14 in the pixel circuit 10 of FIG. 9.

As described above, in the second embodiment, the anode voltage of the light emitting element 7 is fixed, and the current flowing through the cathode can be corrected in consideration of the variation in the threshold voltage of the drive transistor 13. Also in the second embodiment, as in FIG. 3 or FIG. 8, the correction processing by the correction circuit 21 is performed before the head subframe, and the light emission processing of the first to eighth subframes can be performed by reflecting the result of the correction processing.

### Third Embodiment

In the first and second embodiments described above, the correction period in which the correction circuit 21 performs the correction processing is provided before the start of the head subframe among the plurality of subframes obtained by dividing one frame. The correction period performed by the correction circuit 21 does not necessarily have to be before the start of the head subframe, and may be before the start of any subframe. Furthermore, in the first and second embodiments described above, the correction period by the correction circuit 21 is provided only once before the start of the head subframe among the plurality of subframes obtained by dividing one frame, but a plurality of correction periods may be provided within one frame period.

A pixel circuit 10 according to a third embodiment described below has a circuit configuration similar to that of the pixel circuit 10 in FIGS. 2, 7, 9, or 10.

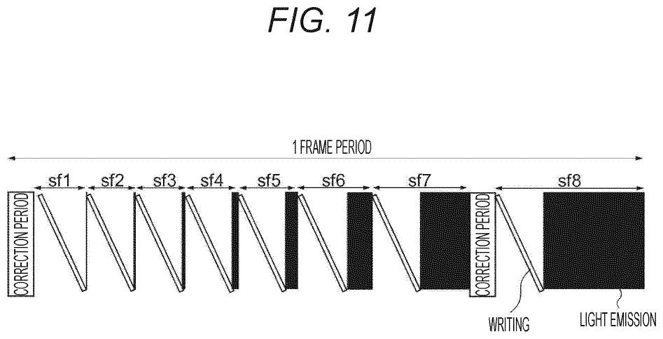

FIG. 11 is an operation timing diagram of the pixel circuit 10 according to the third embodiment. In the pixel circuit 10 of FIG. 11, one frame is divided into eight subframes, and gradation display by the pulse width modulation method is performed. The pixel circuit 10 in FIG. 11 illustrates an example in which the correction period by the correction circuit 21 is provided before the start of the head subframe sf1 and before the start of the last subframe sf8.

Since the period of the last subframe sf8 is the longest among the subframes sf1 to sf8, the light emission processing of the subframe sf8 can be performed after correcting the variation in the threshold voltage of the drive transistor 13 immediately before by performing the correction processing by the correction circuit 21 immediately before the last subframe sf1.

As described above, the correction period by the correction circuit 21 can be provided before the start of any subframe among the subframes sf1 to sf8, and various modifications are conceivable as places where the correction period is provided.

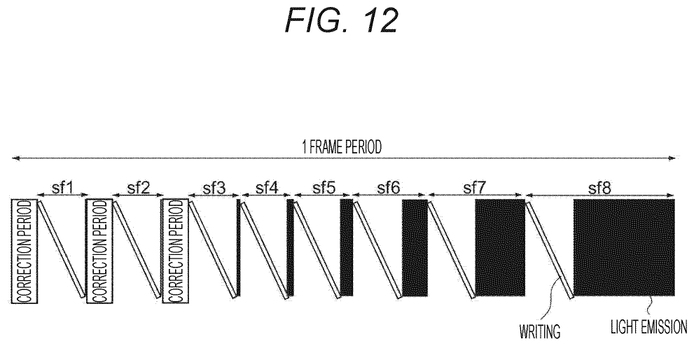

FIG. 12 is an operation timing diagram according to a modification of FIG. 11. In FIG. 12, a correction period by the correction circuit 21 is provided before the start of three subframes sf1 to sf3 from the head among the plurality of subframe periods. There is a possibility that the threshold voltage of the drive transistor 13 cannot be completely corrected only by one time of correction processing by the correction circuit 21. Accordingly, the correction processing is performed a plurality of times before the light emission processing of the plurality of subframes sf1 to sf3 having a short light emission period. Thus, on and after the subframe sf4, the current in which the variation in the threshold voltage of the drive transistor 13 is accurately corrected can flow to the light emitting element 7 without performing the correction processing.

As described above, in the third embodiment, since the correction period by the correction circuit 21 is provided before the start of any number of subframes among the plurality of subframes obtained by dividing one frame, it is possible to cause a current in consideration of the variation in the threshold voltage of the drive transistor 13 to flow through the light emitting element 7 when the light emission processing of any subframe is performed.

As described in the first to third embodiments, the pixel circuit 10 according to the present disclosure includes a subframe in which the light emission processing is performed after the correction processing is performed by the correction circuit 21, and a subframe in which the light emission processing is performed without performing the correction processing. The number of correction periods in which the correction process is performed is not necessarily limited to one, and a plurality of correction periods may be provided. In a case where two or more correction periods are provided, the correction periods may be provided before a plurality of consecutive subframes, or may be provided before discontinuous subframes.

### Application Examples of Display Device 1 and Electronic Apparatus According to Present Disclosure

### First Application Example

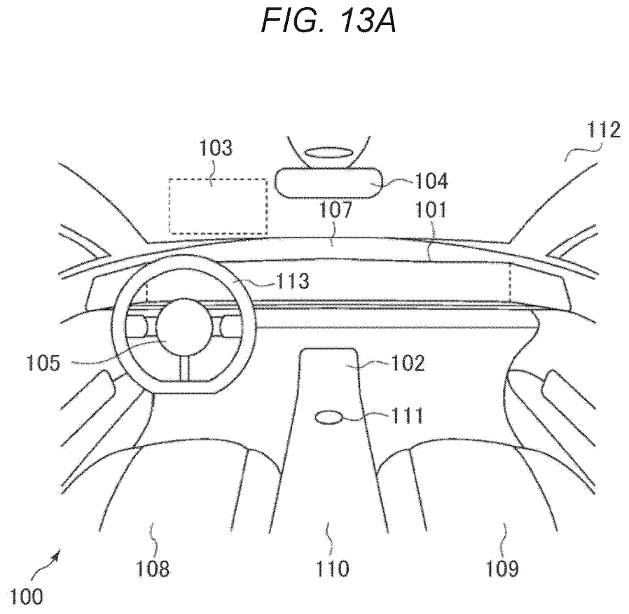

The display device 1 and an electronic apparatus 50 according to the present disclosure can be used for various applications. FIGS. 13A and 13B are views illustrating an internal configuration of a vehicle 100 as a first application example of the electronic apparatus 50 including the display device 1 according to the present disclosure. FIG. 13A is a diagram illustrating an internal state of the vehicle 100 from a rear side to a front side of the vehicle 100, and FIG. 13B is a diagram illustrating an internal state of the vehicle 100 from an oblique rear side to an oblique front side of the vehicle 100.

The vehicle 100 of FIGS. 13A and 13B includes a center display 101, a console display 102, a head-up display 103, a digital rear mirror 104, a steering wheel display 105, and a rear entertainment display 106.

The center display 101 is arranged on a dashboard 107 at a location facing a driver seat 108 and a passenger seat 109. FIG. 13 illustrates an example of the center display 101 having a horizontally long shape extending from the side of the driver seat 108 to the side of the passenger seat 109, but the screen size and arrangement location of the center display 101 are arbitrary. The center display 101 can display information sensed by the various sensors. As a specific example, the center display 101 can display a captured image captured by an image sensor, an image of a distance to an obstacle in front of or on a side of the vehicle, the distance being measured by a ToF sensor, a passenger's body temperature detected by an infrared sensor, and the like. The center display 101 can be used to display, for example, at least one of safety-related information, operation-related information, a life log, health-related information, authentication/identification-related information, or entertainment-related information.

The safety-related information is information of doze sensing, looking-away sensing, sensing of mischief of a child riding together, presence or absence of wearing of a seat belt, sensing of leaving of an occupant, and the like, and is information sensed by the sensor arranged to overlap with a back surface side of the center display 101, for example. The operation-related information senses a gesture related to an operation performed by an occupant, using a sensor. The sensed gestures may include an operation of various types of equipment in the vehicle 100. For example, operations of air conditioning equipment, a navigation device, an AV device, a lighting device, and the like are sensed. The lifelogs include lifelogs of all the occupants. For example, the lifelogs include an action record of each occupant in the vehicle. By acquiring and storing the life log, it is possible to check a state of the occupant at a time of an accident. The health-related information senses the body temperature of an occupant by using a temperature sensor, and estimates the health condition of the occupant on the basis of the sensed body temperature. Alternatively, the face of the occupant may be imaged by using an image sensor, and the health condition of the occupant may be estimated from the imaged facial expression. Moreover, a conversation may be made with an occupant in automatic voice, and the health condition of the occupant may be estimated on the basis of the contents of a response from the occupant. The authentication/identification-related information includes a keyless entry function of performing face authentication using a sensor, and a function of automatically adjusting a seat height and position through face identification. The entertainment-related information includes a function of detecting, with a sensor, operation information about an AV device being used by an occupant, and a function of recognizing the face of the occupant with a sensor and providing content suitable for the occupant through the AV device.

The console display 102 can be used, for example, to display the life log information. The console display 102 is arranged near a shift lever 111 of a center console 110 between the driver seat 108 and the passenger seat 109. The console display 102 can also display information sensed by the various sensors. Furthermore, the console display 102 may display an image of the surroundings of the vehicle captured by an image sensor, or may display an image of a distance to an obstacle present in the surroundings of the vehicle.

The head-up display 103 is virtually displayed behind a windshield 112 in front of the driver seat 108. The head-up display 103 can be used to display, for example, at least one of the safety-related information, the operation-related information, the life log, the health-related information, the authentication/identification-related information, or the entertainment-related information. Since the head-up display 103 is virtually arranged in front of the driver seat 108 in many cases, the head-up display 103 is suitable for displaying information directly related to an operation of the vehicle 100, such as a speed of the vehicle 100 and a remaining amount of fuel (battery).

The digital rear mirror 104 cannot only display the rear of the vehicle 100 but can also display the state of an occupant in the rear seat, and thus can be used to display the life log information, for example, by disposing the sensor to be superimposed on the back surface side of the digital rear mirror 104.

The steering wheel display 105 is arranged near the center of a steering wheel 113 of the vehicle 100. The steering wheel display 105 can be used to display, for example, at least one of the safety-related information, the operation-related information, the life log, the health-related information, the authentication/identification-related information, or the entertainment-related information. In particular, since the steering wheel display 105 is close to the driver's hand, the steering wheel display 105 is suitable for displaying the life log information such as the body temperature of the driver, or for displaying information regarding an operation of the AV device, air conditioning equipment, or the like.

The rear entertainment display 106 is attached to the back side of the driver seat 108 and the passenger seat 109, and is for the occupant in the rear seat to view. The rear entertainment display 106 can be used to display, for example, at least one of the safety-related information, the operation-related information, the life log, the health-related information, the authentication/identification-related information, or the entertainment-related information. In particular, since the rear entertainment display 106 is in front of the occupant in the rear seat, information related to the occupant in the rear seat is displayed. For example, information regarding an operation of the AV device or the air conditioning equipment may be displayed, or a result of measurement of the body temperature or the like of an occupant in the rear seat with a temperature sensor may be displayed.

As described above, disposing a sensor on the back surface side of the display device 1 makes it possible to measure the distance to an object existing in the surroundings. Optical distance measurement methods are roughly classified into a passive type and an active type. By a method of the passive type, distance measurement is performed by receiving light from an object, without projecting light from a sensor to the object. Methods of the passive type include a lens focus method, a stereo method, a monocular vision method, and the like. Methods of the active type include distance measurement that is performed by projecting light onto an object, and receiving reflected light from the object with a sensor to measure the distance. Methods of the active type include an optical radar method, an active stereo method, an illuminance difference stereo method, a moire topography method, and an interference method. The display device 1 according to the present disclosure can be used in distance measurement by any of these methods.

With a sensor disposed on the back surface side of the display device 1 according to the present disclosure in an overlapping manner, distance measurement of the passive type or the active type described above can be performed.

### Second Application Example

The display device 1 according to the present disclosure is applicable not only to various displays used in vehicles but also to displays mounted on various electronic apparatuses 50.

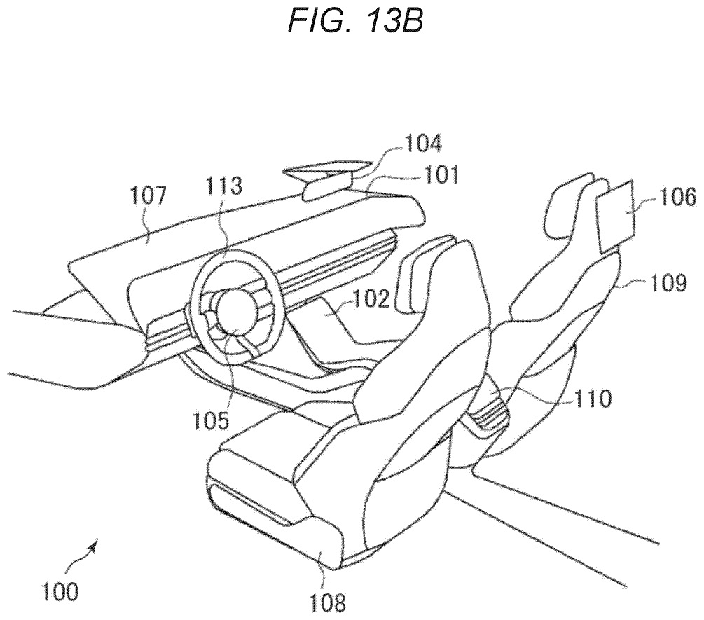

FIG. 14A is a front view of a digital camera 120 as a second application example of the electronic apparatus 50, and FIG. 14B is a rear view of the digital camera 120. The digital camera 120 in FIGS. 14A and 14B illustrates an example of a single-lens reflex camera in which a lens 121 is replaceable, but the electronic apparatus 50 is also applicable to a camera in which the lens 121 is not replaceable.

In the camera of FIGS. 14A and 14B, when a person who captures an image looks into an electronic viewfinder 124 to determine a composition while holding a grip 123 of a camera body 122, and presses a shutter 125 while adjusting focus, the captured image data is stored in a memory in the camera. As illustrated in FIG. 14B, a monitor screen 126 that displays the captured image data or the like and a live image or the like, and the electronic viewfinder 124 are disposed on the back side of the camera. Furthermore, there is a case where a sub screen that displays setting information such as a shutter speed and an exposure value is provided on the upper surface of the camera.

By disposing a sensor, in an overlapping manner, on the back surface side of the monitor screen 126, the electronic viewfinder 124, the sub screen, and the like that are used for the camera, the camera can be used as the display device 1 according to the present disclosure.

### Third Application Example

The display device 1 according to the present disclosure can also be applied to a head-mounted display (hereinafter referred to as an HMD). The HMD can be used for virtual reality (VR), augmented reality (AR), mixed reality (MR), substitutional reality (SR), or the like.

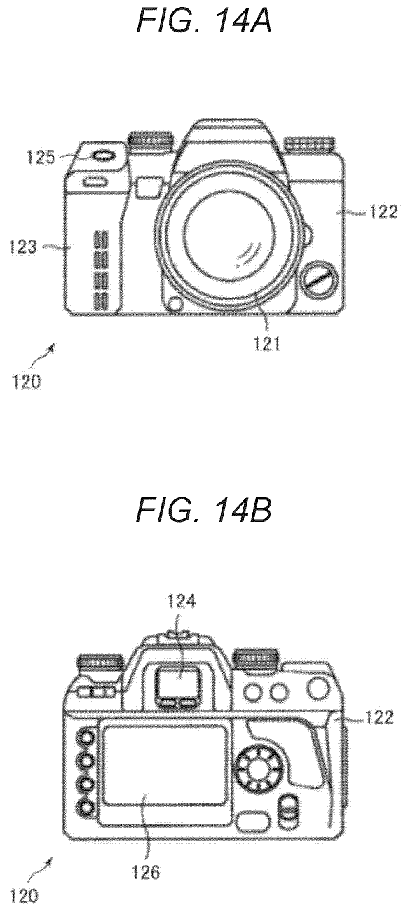

FIG. 15A is an external view of an HMD 130 as a third application example of the electronic apparatus 50. The HMD 130 of FIG. 15A includes a mounting member 131 for attachment to cover human eyes. The mounting member 131 is, for example, hooked and fixed to human ears. A display device 132 is provided inside the HMD 130, and a wearer of the HMD 130 can visually recognize a stereoscopic image and the like with the display device 132. The HMD 130 includes, for example, a wireless communication function and an acceleration sensor, and can switch a stereoscopic image and the like displayed on the display device 132 in accordance with a posture, a gesture, and the like of the wearer.

Furthermore, a camera may be provided in the HMD 130 to capture an image around the wearer, and an image obtained by combining the image captured by the camera and an image generated by a computer may be displayed on the display device 132. For example, by arranging the camera to overlap with the back surface side of the display device 132 visually recognized by the wearer of the HMD 130, capturing an image of the surroundings of the eyes of the wearer with the camera, and displaying the captured image on another display provided on the outer surface of the HMD 130, a person around the wearer can obtain expression of the face and a movement of the eyes of the wearer in real time.

Note that various types of the HMD 130 are conceivable. For example, as illustrated in FIG. 15B, the display device 1 according to the present disclosure can also be applied to smart glasses 130a that display various types of information on glasses 134. The smart glasses 130a of FIG. 15B includes a main body portion 135, an arm portion 136, and a lens barrel portion 137. The main body portion 135 is connected to the arm portion 136. The main body portion 135 is detachable from the glasses 134. The main body portion 135 incorporates a display unit and a control board for controlling the operation of the smart glasses 130a. The main body portion 135 and the lens barrel portion 137 are connected to each other via the arm portion 136. The lens barrel portion 137 emits image light emitted from the main body portion 135 through the arm portion 136, to the lens 138 side of the glasses 134. This image light enters the human eyes through the lens 138. The wearer of the smart glasses 130a of FIG. 15B can visually recognize not only a surrounding situation but also various pieces of information emitted from the lens barrel portion 137 similarly to normal glasses.

### Fourth Application Example

The display device 1 according to the present disclosure can also be applied to a television device (hereinafter referred to as a TV). In recent TVs, a frame tends to be as small as possible from the viewpoint of downsizing and design properties. Accordingly, in a case where a camera to capture an image of a viewer is provided on a TV, it is desirable to arrange the camera so as to overlap with a back surface side of the display panel of the TV.

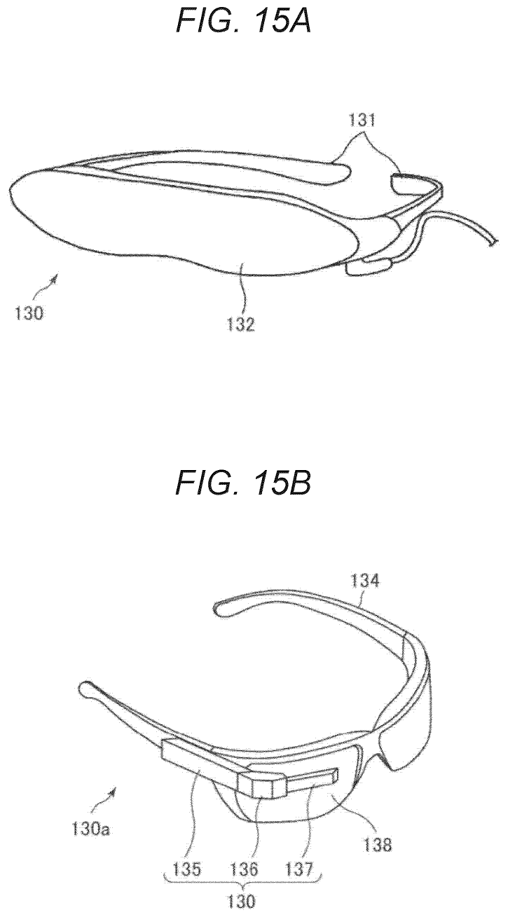

FIG. 16 is an external view of a TV 140 as a fourth application example of the electronic apparatus 50. In the TV 140 of FIG. 16, the frame is minimized, and almost the entire region on the front side is a display area. The TV 140 may incorporate a sensor such as a camera to capture the image of the viewer.

### Fifth Application Example

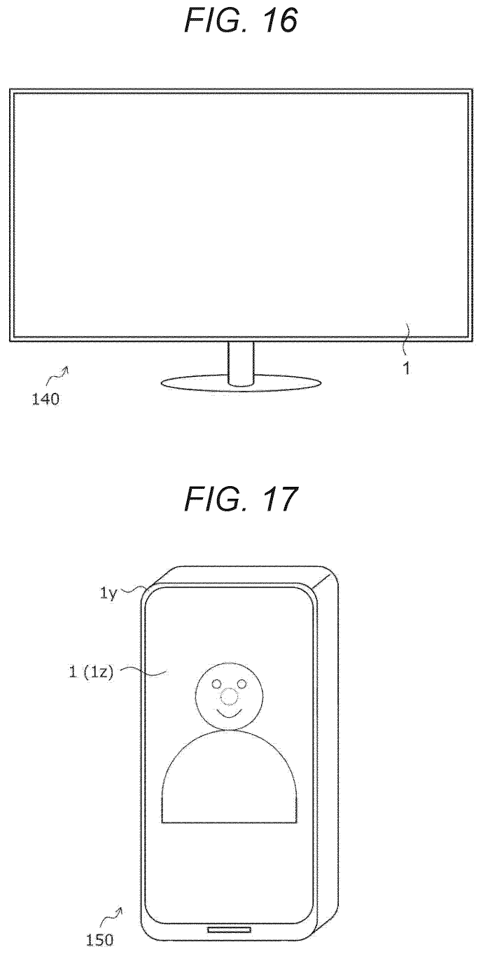

The display device 1 according to the present disclosure can also be applied to a smartphone and a mobile phone. FIG. 17 is an external view of a smartphone 150 as a fifth application example of the electronic apparatus 50. In an example in FIG. 17, a display surface 1z extends to nearly the outer shape of the electronic apparatus 50, and the width of a bezel 1y around the display surface 1z is set to several millimeters or less.

Usually, a front camera is mounted on the bezel 1y in many cases, but an image sensor module functioning as a front camera may be disposed on, for example, a back surface side of a substantially central portion of the display surface 1z. As described above, by providing the front camera on the back surface side of the display surface 1z in this manner, the front camera no longer need to be arranged on the bezel 1y, and thus the width of the bezel 1y can be narrowed.

Note that the present technology can have the following configurations.
(1) A display device that performs gradation display of a plurality of pixels in one frame including a plurality of subframes,
   in which the pixels each include a light emitting element and a pixel circuit that controls a current for driving the light emitting element,
   the pixel circuit includes
   a current source that generates a current for driving the light emitting element, and
   a correction circuit that corrects a variation in the current generated by the current source, and
   the plurality of subframes includes a subframe in which the light emitting element is driven after the variation is corrected by the correction circuit and a subframe in which the light emitting element is driven without correcting the variation by the correction circuit.
(2) The display device according to (1), in which only one subframe in which the light emitting element is driven after the variation is corrected by the correction circuit is provided in the plurality of subframes.
(3) The display device according to (2), in which the subframe in which the light emitting element is driven after the variation is corrected by the correction circuit is a head subframe among the plurality of subframes.
(4) The display device according to (1), in which two or more subframes in which the light emitting element is driven after the variation is corrected by the correction circuit are provided in the plurality of subframes.
(5) The display device according to (4), in which the subframe in which the light emitting element is driven after the variation is corrected by the correction circuit includes two or more subframes not adjacent to each other among the plurality of subframes.
(6) The display device according to (4), in which the subframe in which the light emitting element is driven after the variation is corrected by the correction circuit includes two or more adjacent subframes among the plurality of subframes.
(7) The display device according to (4), in which the subframe in which the light emitting element is driven after the variation is corrected by the correction circuit includes a predetermined number of adjacent subframes including a head subframe among the plurality of subframes.
(8) The display device according to any one of (1) to (7),
   in which each of the plurality of pixels is connected to any one of a plurality of gate lines, and
   a plurality of the correction circuits included in the plurality of pixels corrects variations in current generated by the plurality of current sources in the plurality of pixels connected to the plurality of gate lines at the same timing.
(9) The display device according to any one of (1) to (8),
   in which the pixel circuit includes
   a storage unit that stores pixel data, and
   a first switching element that switches, for each of the plurality of subframes, whether or not to supply the light emitting element with a current corrected by the correction circuit on the basis of the pixel data stored in the storage unit.
(10) The display device according to (9),
   in which the current source includes a second switching element cascode-connected to the first switching element, and
   the correction circuit corrects a threshold voltage of the second switching element.
(11) The display device according to (10),
   in which the first switching element is turned on or off according to the pixel data stored in the storage unit, and
   when the first switching element and the second switching element are turned on, the pixel circuit causes a current corrected according to a threshold voltage of the second switching element to flow from the second switching element to the light emitting element through the first switching element.
(12) The display device according to (10) or (11), further including:
   a bias signal line that supplies a bias signal common to a plurality of the correction circuits included in the plurality of pixels,
   in which the second switching element is turned on when the bias signal reaches a predetermined voltage level.
(13) The display device according to (12),
   in which the correction circuit includes
   a third switching element connected between a gate and a drain of the second switching element,
   a first capacitor connected between the gate of the second switching element and the bias signal line, and
   a second capacitor connected between the gate and the source of the second switching element.
(14) The display device according to (13), in which the plurality of the correction circuits included in the plurality of pixels synchronously turns on or off a plurality of the first switching elements, synchronously turns on or off a plurality of the second switching elements, and synchronously turns on or off a plurality of the third switching elements.
(15) The display device according to any one of (10) to (14), in which conductivity types of the first switching element and the second switching element are the same.
(16) The display device according to any one of (10) to (14), in which conductivity types of the first switching element and the second switching element are different from each other.
(17) The display device according to any one of (10) to (16), further including:
   a fourth switching element that switches whether or not to set an anode of the light emitting element to a first reference voltage,
   in which the first switching element is connected to the anode of the light emitting element, and
   a cathode of the light emitting element is set to a second reference voltage.
(18) The display device according to any one of (10) to (16), further including:
   a fourth switching element that switches whether or not to set a cathode of the light emitting element to a first reference voltage,
   in which the first switching element is connected to the cathode of the light emitting element, and
   an anode of the light emitting element is set to a second reference voltage.
(19) The display device according to any one of (1) to (18), in which light emission periods of the light emitting elements in the plurality of subframes are different from each other.
(20) The display device according to any one of (1) to (18), in which light emission periods of the light emitting elements in the plurality of subframes are the same.

Aspects of the present disclosure are not limited to the above-described individual embodiments, but include various modifications that can be conceived by those skilled in the art, and the effects of the present disclosure are not limited to the above-described contents. That is, various additions, modifications, and partial deletions are possible without departing from the conceptual idea and spirit of the present disclosure derived from the matters defined in the claims and equivalents thereof.

### REFERENCE SIGNS LIST

1 Display device
1y Bezel
1z Display surface
2 Pixel array unit
3 Horizontal drive circuit
4 Vertical drive circuit
5 Bias control circuit
6 Pixel
7 Light emitting element
10 Pixel circuit
11 Memory
12 Switch transistor
13 Drive transistor
14 Reset transistor
15 Offset transistor
16 First inverter
17 Second inverter
18 First transistor
19 Second transistor
20 Current source
21 Correction circuit
22 Transistor
50 Electronic apparatus
100 Vehicle
101 Center display
102 Console display
103 Head-up display
104 Digital rear mirror
105 Steering wheel display
106 Rear entertainment display
107 Dashboard
108 Driver seat
109 Passenger seat
110 Center console
111 Shift lever
112 Windshield
113 Steering wheel
120 Digital camera
121 Lens
122 Camera body
123 Grip
124 Electronic viewfinder
125 Shutter
126 Monitor screen
130a Smart glasses
131 Mounting member
132 Display device
134 Glasses
135 Main body unit
136 Arm portion
137 Lens barrel portion
138 Lens
150 Smartphone

What is claimed is:

1. A display device that performs gradation display of a plurality of pixels in one frame including a plurality of subframes,
wherein the pixels each include a light emitting element and a pixel circuit that controls a current for driving the light emitting element,
the pixel circuit includes
a current source that generates a current for driving the light emitting element, and
a correction circuit that corrects a variation in the current generated by the current source, and
the plurality of subframes includes a subframe in which the light emitting element is driven after the variation is corrected by the correction circuit and a subframe in which the light emitting element is driven without correcting the variation by the correction circuit.

2. The display device according to claim 1, wherein only one subframe in which the light emitting element is driven after the variation is corrected by the correction circuit is provided in the plurality of subframes.

3. The display device according to claim 2, wherein the subframe in which the light emitting element is driven after the variation is corrected by the correction circuit is a head subframe among the plurality of subframes.

4. The display device according to claim 1, wherein two or more subframes in which the light emitting element is driven after the variation is corrected by the correction circuit are provided in the plurality of subframes.

5. The display device according to claim 4, wherein the subframe in which the light emitting element is driven after the variation is corrected by the correction circuit includes two or more subframes not adjacent to each other among the plurality of subframes.

6. The display device according to claim 4, wherein the subframe in which the light emitting element is driven after the variation is corrected by the correction circuit includes two or more adjacent subframes among the plurality of subframes.

7. The display device according to claim 4, wherein the subframe in which the light emitting element is driven after the variation is corrected by the correction circuit includes a predetermined number of adjacent subframes including a head subframe among the plurality of subframes.

8. The display device according to claim 1,
wherein each of the plurality of pixels is connected to any one of a plurality of gate lines, and
a plurality of the correction circuits included in the plurality of pixels corrects variations in current generated by the plurality of current sources in the plurality of pixels connected to the plurality of gate lines at a same timing.

9. The display device according to claim 1,
wherein the pixel circuit includes
a storage unit that stores pixel data, and
a first switching element that switches, for each of the plurality of subframes, whether or not to supply the light emitting element with a current corrected by the correction circuit on a basis of the pixel data stored in the storage unit.

10. The display device according to claim 9,
wherein the current source includes a second switching element cascode-connected to the first switching element, and
the correction circuit corrects a threshold voltage of the second switching element.

11. The display device according to claim 10,
wherein the first switching element is turned on off according to the pixel data stored in the storage unit, and
when the first switching element and the second switching element are turned on, the pixel circuit causes a current corrected according to a threshold voltage of the second switching element to flow from the second switching element to the light emitting element through the first switching element.

12. The display device according to claim 10, further comprising:
a bias signal line that supplies a bias signal common to a plurality of the correction circuits included in the plurality of pixels,
wherein the second switching element is turned on when the bias signal reaches a predetermined voltage level.

13. The display device according to claim 12,
wherein the correction circuit includes
a third switching element connected between a gate and a drain of the second switching element,
a first capacitor connected between the gate of the second switching element and the bias signal line, and
a second capacitor connected between the gate and the source of the second switching element.

14. The display device according to claim 13, wherein the plurality of the correction circuits included in the plurality of pixels synchronously turns on or off a plurality of the first switching elements, synchronously turns on or off a plurality of the second switching elements, and synchronously turns on or off a plurality of the third switching elements.

15. The display device according to claim 10, wherein conductivity types of the first switching element and the second switching element are same.

16. The display device according to claim 10, wherein conductivity types of the first switching element and the second switching element are different from each other.

17. The display device according to claim 10, further comprising:
a fourth switching element that switches whether or not to set an anode of the light emitting element to a first reference voltage,
wherein the first switching element is connected to the anode of the light emitting element, and
a cathode of the light emitting element is set to a second reference voltage.

18. The display device according to claim 10, further comprising:
a fourth switching element that switches whether or not to set a cathode of the light emitting element to a first reference voltage,
wherein the first switching element is connected to the cathode of the light emitting element, and
an anode of the light emitting element is set to a second reference voltage.

19. The display device according to claim 1, wherein light emission periods of the light emitting elements in the plurality of subframes are different from each other.

20. The display device according to claim 1, wherein light emission periods of the light emitting elements in the plurality of subframes are same.
